(19) United States
(12) Patent Application Publication
(10) Pub. No.: US 2026/0011985 A1
(43) Pub. Date: Jan. 8, 2026

(54) LASER SYSTEM FOR GENERATING SEGMENTED LINE BEAM

(71) Applicant: DILAS Diodenlaser GmbH, Mainz (DE)

(72) Inventors: Tobias KÖNNING, Nackenheim (DE); Bernd KÖHLER, Saulheim (DE); Andreas BAYER, Mainz (DE)

(73) Assignee: DILAS Diodenlaser GmbH, Mainz (DE)

(21) Appl. No.: 18/763,641

(22) Filed: Jul. 3, 2024

(51) Int. Cl. H01S 5/40; H01M 50/531

(52) U.S. Cl. CPC H01S 5/4075; H01M 50/531

(57) ABSTRACT

A laser system for generating a segmented line beam includes a laser module emitting an input laser beam, and a one-dimensional array of prisms, or mirrors, that splits the input laser beam into a respective plurality of output laser beams propagating in a common plane but diverging from each other, in the common plane, when propagating away from the array of prisms. A field lens, or mirror, projects the output laser beams onto a target plane to form a segmented line beam at the target plane. The laser system is energy efficient by splitting rather than masking the input laser beam. The laser system is capable of achieving superior segment-to-segment consistency and can be configured to produce each segment with a top-hat intensity distribution. Furthermore, the laser system can be reconfigured with relative ease to meet different requirements in terms of segment length and width as well as segment-to-segment spacings.

### TECHNICAL FIELD OF THE INVENTION

The present invention relates in general to laser line-beam generation. The present invention relates in particular to the generation of a segmented laser line-beam, for example for use in laser drying or semiconductor processing.

### DISCUSSION OF BACKGROUND ART

In large part due to their high energy density, electrochemical batteries such as lithium-ion batteries are the preferred power source in many different applications ranging from small portable electronic devices to electric vehicles. The basic unit of such a battery cell consists of an anode, a cathode, and a separator therebetween. Each of the anode and cathode is a metal foil coated with an active material. The active material is the component that participates in the electrochemical reactions within the battery. The active material of the cathode is predominantly an oxide that contains mobile ions, for example lithium or sodium, whereas the active material of the anode typically consists primarily of carbon forms, for example graphite and/or silicon.

For both the cathode and the anode, the active material is coated on the metal foil in the form of a slurry. In a typical manufacturing line, a large coil of metal foil is provided on a reel. The metal foil is transferred from this initial reel to another reel via a coating apparatus. The coating apparatus forms one or more coating “lanes” along the length of the metal foil. The slurry deposited by the coating apparatus is a mixture of the active material, a binder that helps adhere the active material to the metal foil, and a solvent used to ensure that the active material and binder can be evenly mixed and applied to the metallic foil. The coating apparatus subjects the slurry to a drying process that removes the solvent. This drying process is conventionally carried out using convection ovens or infrared-lamp drying. While convection ovens are widely used for this purpose, they are physically large and consume a large amount of energy. Infrared lamps provide a more compact solution as well as some improvement in terms of energy efficiency. Yet, the conventional drying process is still one of the most energy consuming parts of electrochemical battery production.

A line beam is a laser beam that has a long, narrow cross section resembling a line. There are several ways to shape a circular laser beam into a line beam. Most commonly, one or more cylindrical lenses are used to shape a circular Gaussian laser beam into a line beam. Line beams are commonly utilized in materials processing tasks, such as annealing, especially within the context of semiconductor processing. Line beams are also employed in imaging and scanning applications, including barcode scanning, three-dimensional profiling, and biomedical imaging. Some of these applications benefit from, or require, that the line beam has a uniform intensity along its length so as to provide consistent illumination of the target. In these situations, the laser intensity distribution along the length of the line is ideally a top-hat distribution characterized by an approximately constant intensity along the full length of the line with sharp drop-offs at the ends. Transformation of a circular Gaussian laser beam into a line beam with a top-hat distribution can be achieved with, e.g., a lens array or a Powell lens. A Powell lens is an aspheric cylindrical lens with a uniquely shaped apex. Line beams can also be generated by stitching together several individual laser beams. For example, the collection of laser beams emitted by a suitably shaped laser diode array can be formed into a line beam. Similarly, the fiber output ports of several fiber-coupled laser modules can be arranged in a one-dimensional array, such that the laser beams emitted from the fiber output ports can be formed into a line beam.

Certain applications, such as silicon annealing, may call for the use of a segmented line beam. A mask may be used to segment a line beam into a series of shorter line beams. The mask has openings that transmit only the desired segments of a line beam incident on the mask, while the remaining portions of the line beam are blocked.

### SUMMARY OF THE INVENTION

Laser drying is as an alternative to conventional methods for drying battery electrode coatings. Laser drying can be significantly more efficient than drying in convection ovens and even infrared lamp drying, especially when using high-efficiency laser sources. Laser drying of battery electrode coatings can be performed with an energy consumption level that is only between about 10% and 50% of the energy consumption of convection oven and infrared lamp drying. In the battery electrode coating process, a single coating lane on a metal foil may be dried by passing the metal foil through a laser line-beam having a length that matches the width of the coating lane. For best drying results, the line beam may have a top-hat intensity distribution in its lengthwise dimension, with the length of the line matching the width of the coating lane. However, such uniform line-beam illumination is not suitable for simultaneously drying several parallel coating lanes. If a bare portion of the metal foil between two coating lanes were to be irradiated as intensely as the actual coating lanes, this bare metal foil would heat up rapidly and cause the adjacent coating-lane edges to over-dry and possibly delaminate. This issue can be overcome by utilizing a segmented line beam, with the length of each segment matching the width of a corresponding coating lane.

Disclosed herein is a laser system that generates a segmented line beam at a target plane. The presently disclosed laser system is suitable for laser drying multiple parallel coating lanes on a metal foil, for example as needed in a battery electrode coating process. The present laser system may also be useful in a range of other applications, such as semiconductor processing.

The present laser system utilizes a prism array, or a mirror array, to split an input laser beam into a plurality of output laser beams. A field lens or mirror projects the output laser beams to the target plane. In the absence of the prism/mirror array, the laser system would relay a single output beam to the target plane. However, beam deflection and splitting by the prism/mirror array produces multiple copies of this output beam at the target plane (although each of these output beams shares the power of the single output beam produced in the absence of the prism/mirror array). These multiple copies are situated along a line, thereby forming a segmented line beam. A top-hat spatial intensity distribution of each line-beam segment at the target plane can be achieved when the input laser beam is incident on the prism/mirror array with a uniform angular intensity distribution. A desired length-to-width aspect ratio of the line-beam segments at the target plane may be achieved by suitable choice of laser source properties and/or incorporation of cylindrical lenses (or mirrors).

There are several advantages associated with the present laser system. The laser system is energy efficient, capable of achieving superior segment-to-segment consistency, and reconfigurable. Addressing first energy efficiency, the present approach does not need to discard laser light in order to form the segmented laser line. The present approach thus provides a low-loss solution as compared to mask-based line-beam segmentation. This is particularly advantageous in applications that require a large amount of laser energy, such as laser drying of battery electrode coatings. In such applications, the low laser-light loss of the present laser system may amount to a significant reduction of the overall energy consumption of the battery-electrode manufacturing process.

The prism/mirror array may be configured such that each output laser beam samples the full width, or at least the same width, of the input laser beam. This results in excellent segment-to-segment consistency at the target plane, even in scenarios where the angular intensity distribution of the input beam, as incident on prism/mirror array, is non-uniform and/or variable. For further comparison, consider operating a laser diode array to produce a segmented line beam. With this technique, segment-to-segment consistency would be directly sensitive to the variability between individual laser diodes. The present approach is not afflicted by this issue.

The design of the prism/mirror array may be tailored to produce a desired spacing between each pair of adjacent line-beam segments independently of each other and independently of the segment length. The prism/mirror array may also be designed to split the power of the input laser beam unevenly between the output laser beams, if so desired. Since the prism/mirror array does not affect the focusing properties of the laser system, prism/mirror arrays of different designs may be swapped in and out to change, e.g., the number of line-beam segments, the relative power of the line-beam segments, and the inter-segment spacing, as needed to perform different processing tasks. It is also possible to swap in and out cylindrical telescopes to manipulate the overall length and width of the segmented line beam and/or the aspect ratio of individual line-beam segments. In short, the present laser system can, with relative ease, be reconfigured to address different process requirements.

In one aspect of the invention, a laser system for generating a segmented line beam includes a laser module to emit an input laser beam and a one-dimensional array of prisms arranged to receive the input laser beam. The array of prisms is distributed along a first transverse dimension of the input laser beam and organized in a plurality of prism sets interleaved with each other in the array. Each prism set of the plurality of prism sets is to impose on the input laser beam a different respective deflection angle in a propagation plane spanned by the first transverse dimension and a longitudinal axis of the input laser beam, whereby the plurality of prism sets splits the input laser beam into a respective plurality of output laser beams diverging from each other when propagating away from the array of prisms. The laser system further includes a field lens or mirror arranged to project the output laser beams onto a target plane to form a segmented line beam at the target plane.

In another aspect of the invention, a laser system for generating a segmented line beam includes a laser module to emit an input laser beam and a one-dimensional array of planar mirror surfaces arranged to receive the input laser beam. The array of mirror surfaces is distributed along a direction that is (a) parallel to a propagation plane spanned by a first transverse dimension and a longitudinal axis of the input laser beam and (b) at oblique angles to the first transverse dimension and the longitudinal axis. The array of mirror surfaces is organized in a plurality of mirror-surface sets interleaved with each other in the array. Each mirror surface set of the plurality of mirror surface sets is to impose on the input laser beam a different respective deflection angle in the propagation plane, whereby the plurality of mirror surface sets splits the input laser beam into a respective plurality of output laser beams diverging from each other when propagating away from the array of mirrors. The laser system further includes a field lens or mirror arranged to project the output laser beams onto a target plane to form a segmented line beam at the target plane.

### BRIEF DESCRIPTION OF THE DRAWINGS

The accompanying drawings, which are incorporated in and constitute a part of the specification, schematically illustrate preferred embodiments of the present invention, and together with the general description given above and the detailed description of the preferred embodiments given below, serve to explain principles of the present invention.

FIGS. 1A and 1B illustrate a laser system that utilizes a prism array to generate a segmented line beam at a target plane, according to an embodiment.

FIGS. 2A and 2B illustrate a prism array configured to split an input laser beam into a plurality of output laser beams, according to an embodiment.

FIG. 3 illustrates imaging, in the laser system of FIGS. 1A and 1B, of an exemplary initial transverse spatial intensity distribution of an input laser beam to form a segmented line beam.

FIG. 4 illustrates a coating apparatus that utilizes the laser system of FIGS. 1A and 1B to simultaneously laser dry a plurality of parallel coating lanes on a metal foil, according to an embodiment.

FIG. 5 illustrates a prism array configured to split an input laser beam into a plurality of output laser beams with uneven power sharing between the output laser beams, according to an embodiment.

FIG. 6 illustrates a monolithic prism array, according to an embodiment.

FIGS. 7A and 7B illustrate a laser system that utilizes a prism array to generate a segmented line beam and utilizes a cylindrical telescope to manipulate the aspect ratio of individual line-beam segments, according to an embodiment.

FIG. 8 illustrates a laser system that utilizes a mirror array to generate a segmented line beam, according to an embodiment.

FIG. 9 illustrates one example of the mirror array of the FIG. 8 laser system.

FIGS. 10A and 10B illustrate a two-dimensional prism array, according to an embodiment.

FIGS. 11A and 11B illustrate a laser system that utilizes the prism array of FIGS. 10A and 10B to generate plurality of segmented line beams situated side-by-side, according to an embodiment.

FIG. 12 illustrates imaging, in the laser system of FIGS. 11A and 11B, of an exemplary initial transverse spatial intensity distribution of an input laser beam to form the plurality of segmented line beams.

### DETAILED DESCRIPTION OF THE INVENTION

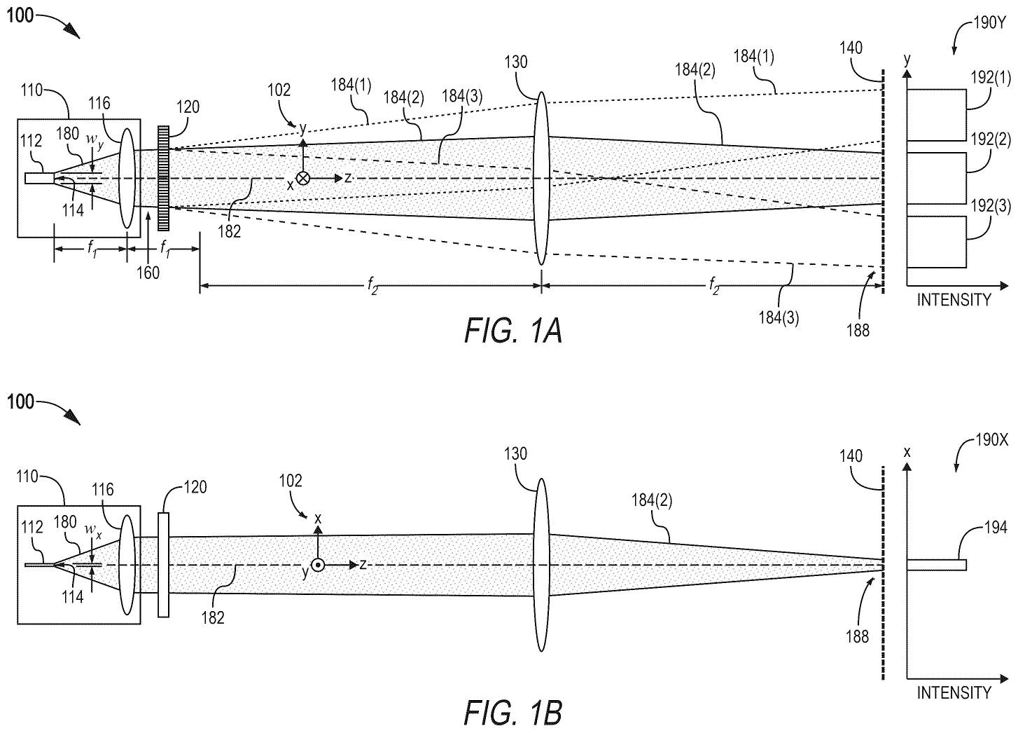

Referring now to the drawings, wherein like components are designated by like numerals, FIGS. 1A and 1B illustrate one laser system 100 that utilizes a prism array 120 to generate a segmented line beam at a target plane 140. Target plane 140 is a virtual plane. A workpiece to be processed by segmented line beam 188, such as a coated metal foil or a semiconductor substrate, may be positioned at target plane 140. FIGS. 1A and 1B show orthogonal cross sections of laser system 100 taken in the yz- and xz-planes, respectively, of a cartesian coordinate system 102. Herein, reference to x-, y-, and z-axes and associated planes and dimensions refer to coordinate system 102. The z-axis coincides with a longitudinal axis 182 of laser system 100.

Laser system 100 includes a laser module 110, prism array 120, and a field lens 130. Laser module 110 includes a laser source 112 that emits an input laser beam 180 along longitudinal axis 182, and a collimation lens 116 that collimates input beam 180. Prism array 120 deflects at least portions of input beam 180 in the yz-plane to split input beam 180 into a plurality of output laser beams 184 propagating away from prism array 120 at non-zero angles to each other in the yz-plane, as seen in FIG. 1A. Field lens 130 focuses output beams 184 at target plane 140.

In the depicted embodiment, prism array 120 splits input beam 180 into three output laser beams: an output beam 184(1) indicated by short-dashed outline, an output beam 184(2) indicated by solid outline and shading, and an output beam 184(3) indicated by longer-dashed outline. Output beam 184(2) is an undeflected fraction of input beam 180. Output beams 184 initially overlap at prism array 120 but diverge from each other when propagating away from prism array 120. Prism array 120 does not introduce propagation-direction differences between output beams 184 orthogonally to the y-axis. However, due to the propagation-direction differences introduced in the yz-plane, output beams 184(1) and 184(3) depart from the xz-plane. Ultimately only output beam 184(2) remains visible in the xz-plane. More generally, prism array 120 may split input beam 180 into two or more output beams 184. One of these output beams 184 may be an undeflected fraction of input beam 180.

Collimation lens 116 and field lens 130 form an imaging system that images an output face 114 of laser source 112 onto target plane 140. The distance from output face 114 to collimation lens 116 matches the focal length f₁ of collimation lens 116, the distance between collimation lens 116 and field lens 130 matches the sum of focal length f₁ and the focal length f₂ of field lens 130, and the distance from field lens 130 to target plane 140 matches focal length f₂. Due to the splitting of input beam 180 by prism array 120 into multiple output beams 184 having different propagation directions, multiple beam images appear at target plane 140. The images are offset from each other in the y-dimension. Output beams 184 therefore form a segmented line beam 188 at target plane 140. Segmented line beam 188 is oriented along the y-axis and has one segment for each output beam 184 generated by prism array 120.

At target plane 140, segmented line beam 188 is characterized by a spatial intensity distribution 190Y in the y-dimension and a spatial intensity distribution 190X in the x-dimension. Intensity distribution 190Y has a separate lobe 192 for each output beam 184. Intensity distribution 190X has only a single lobe 194 since no splitting takes place orthogonally to the y-axis. Each y-dimension lobe 192, together with the single x-dimension lobe 194, represents an image of the spatial intensity distribution of input beam 180 at the output face 114 of laser source 112. While the depicted examples of lobes 192 and 194 have a top-hat profile, other profiles can be achieved with laser system 100.

Although not shown in FIG. 1, prism array 120 may deflect all output beams 184 by a common non-zero angle in the xz-plane, so as to fold longitudinal axis 182 in the xz-plane. Additionally, while the average deflection angle introduced by prism array 120 in the yz-plane is shown in FIG. 1A as being zero, the average deflection angle may be non-zero such that longitudinal axis 182 is folded in the yz-plane.

Focal length f₂ of field lens 130 defines the working distance to target plane 140. In the depicted example, focal length f₂ of field lens 130 is significantly greater than focal length f₁ of collimation lens 116. Focal length f₂ may be one or more orders of magnitude greater than focal length f₁, so as to provide a practical working distance between field lens 130 and a workpiece, e.g., metal foil, positioned at target plane 140. In one embodiment, focal length f₂ is in the range between 50 and 200 centimeters (cm). This embodiment provides a practical working distance for applications where segmented line beam 188 needs to irradiate a large area at target plane 140, such as in laser drying of battery electrode coatings.

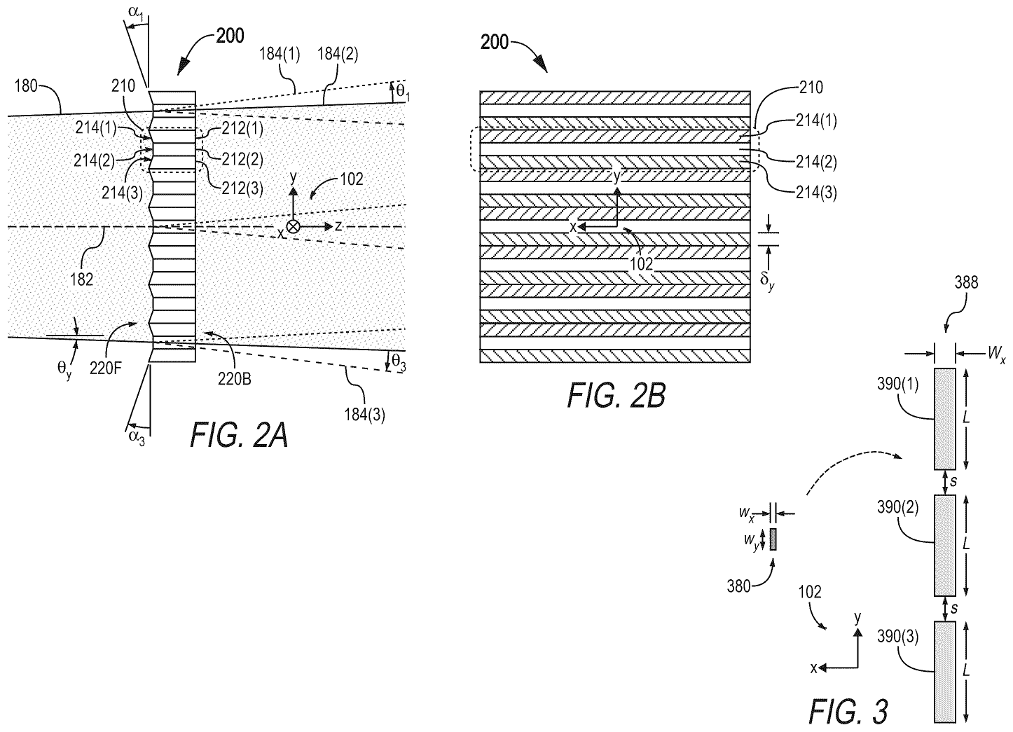

FIGS. 2A and 2B illustrate one prism array 200 configured to split an input laser beam into a plurality of output laser beams. Prism array 200 is an embodiment of prism array 120. FIG. 2A is a cross sectional side-view of prism array 120 taken in the yz-plane, further showing the action of prism array 200 on input beam 180 when prism array 200 is implemented in laser system 100. Prism array 200 has a frontside 220F, facing input beam 180, and a backside 220B. FIG. 2B is a front view of frontside 220F of prism array 200.

In the depicted example, each prism block 210 includes three prisms 212(1), 212(2), and 212(3) having respective planar surfaces 214(1), 214(2), and 214(3) on frontside 220F. Surfaces 214(1), 214(2), and 214(3) are oriented at three different angles with respect to longitudinal axis 182. The collection of surfaces 214 of prism blocks 210 form a multi-faceted surface on frontside 220F. Prism array 200 may include between 1 and 200 prism blocks 210. While a single prism block 210 is sufficient to produce segmentation, a greater number of prism blocks 210 generally yields better segment-to-segment consistency. Thus, in certain embodiments, prism array 200 includes at least 2 prism blocks 210. Surface 214(2) is orthogonal to longitudinal axis 182. Surface 214(1) faces somewhat in the negative y-axis direction and is oriented at a counter-clockwise angle α₁ to surface 214(2). Surface 214(3) faces somewhat in the positive y-axis direction and is oriented at a clockwise angle α₃ surface 214(2). The back surface of each prism 212, on backside 220B, is planar and orthogonal to longitudinal axis 182. For example, as depicted in FIG. 2A, the back surfaces of all prisms 212 of prism array 200 may be coplanar.

Portions of input beam 180 incident on surfaces 214(2) pass through prism array 120 undeflected to form output beam 184(2). Portions of input beam 180 incident on surfaces 214(1) are deflected in the positive y-axis direction to form output beam 184(1) propagating at a counter-clockwise angle θ₁ with respect to output beam 184(2). Portions of input beam 180 incident on surfaces 214(3) are deflected in the negative y-axis direction to form output beam 184(3) propagating at a clockwise angle θ₃ with respect to output beam 184(2). Depending on the values of angles α₁ and α₃, angles θ₁ and θ₃ may or may not have the same magnitude.

When prism array 200 includes more than one prism block 210, prism array 200 includes a set of identical prisms 212(1), a set of identical prisms 212(2), and a set of identical prisms 212(3). These three sets of prisms are interleaved with each other in prism array 200. This interleaved nature of the prism sets of prism array 200 has certain advantages. Provided that the number of prism blocks 210 intersecting input beam 180 is substantial, e.g., 8 or more, each class of surfaces 214 is represented across essentially the full y-dimension width of input beam 180. Therefore, each output beam 184 samples essentially the same width of input beam 180. In the depicted example, prism array 200 spans the full width of input beam 180, and each output beam 184 therefore samples essentially the full width of input beam 180. The interleaved nature of the prism sets of prism array 200 ensures excellent consistency between the different segments of segmented line beam 188, even if input beam 180 is spatially non-uniform.

The depicted embodiment of prism array 200 is readily extendable to splitting into a different number of output beams 184, e.g., between 2 and 20 output beams 184. The number of output beams 184 equals the number of differently oriented surfaces 214 in each prism block 210. Regardless of the number of differently oriented surfaces 214 in each prism block 210, prism array 200 may be configured to transmit one output beam undeflected or, alternatively, impose a non-zero deflection angle on every output beam 184. Furthermore, prism array 200 may be oriented such that surfaces 214 are located on backside 220B.

FIG. 3 illustrates imaging, in laser system 100, of an exemplary initial transverse spatial intensity distribution of input beam 180 to form segmented line beam 188. FIG. 3 depicts two-dimensional spatial intensity distributions in the xy-plane. At output face 114 of laser source 112, input beam 180 has a spatial intensity distribution 380. At target plane 140, segmented line beam 188 has a spatial intensity distribution 388 that includes a plurality of separate line-beam segments 390 offset from each other in the y-axis direction.

Referring now to FIGS. 1A, 1B, and 3 in combination, output face 114 has a rectangular shape with widths wₓ and w_{y} in the x- and y-dimensions, respectively. Assuming that each output beam 184 samples the full width of input beam 180, this rectangular shape is imaged onto target plane 140 with the magnification M defined by the respective focal lengths f₁ and f₂ of collimation lens 116 and field lens 130. Thus, the length L of each line-beam segment 390 in the y-dimension equals Mw_{y}, and the width Wₓ of each line-beam segment 390 in the x-dimension equals Mwₓ. In the depicted embodiment, w_{y} exceeds wₓ such that each line-beam segment 390 is elongated in the y-dimension. In other words, each line-beam segment 390 is itself a line beam. In another embodiment, not depicted, wₓ and w_{y} are more similar or even identical, and individual line-beam segments 390 do not resemble a line beam. The shape of output face 114 may also be different than depicted, for example elliptical or circular.

The separation s between adjacent line-beam segments 390 is determined by the deflection angles imposed by prism array 120, together with the y-dimension-divergence angle θ_{y} of input beam 180 as incident on prism array 120 (indicated in FIG. 2 for prism array 200). The difference in deflection angles between adjacent output beams 184 affects the center-to-center spacing between corresponding line-beam segments 390 in the y-dimension. Although input beam 180 has been collimated prior to prism array 120, the non-zero width w_{y} of input beam 180 at output face 114 of laser source 112 produces a non-zero divergence angle θ_{y} of input beam 180 in the y-dimension. Divergence angle θ_{y} is an increasing function of width w_{y}, and length L of line-beam segments 390 is an increasing function of divergence angle θ_{y}. A non-zero separation s, needed to produce segmented line beam 188, requires that the deflection-angle difference between adjacent output beams 184 exceeds 2θ_{y}, such that the center-to-center spacing between adjacent output beams 184 exceeds segment length L. For any given divergence angle θ_{y} and corresponding length L, a desired separation s between adjacent line-beam segments 390 can be achieved by suitable design of the deflection angles imposed by prism array 120. Prism array 120 may be configured to produce the same separation s between all pairs of adjacent line-beam segments 390. Alternatively, prism array 120 may be configured to produce different separations s between at least some pairs of adjacent line-beam segments 390.

Assuming again that each output beam 184 samples the full width of input beam 180, each line-beam segment 390 generated by laser system 100 has not only the same general shape but the same spatial intensity distribution as input beam 180 at output face 114. Thus, the spatial intensity distribution of line-beam segments 390 can be selected by appropriate choice of laser source 112 and the associated intensity distribution 380 at output face 114. In one implementation, laser source 112 is a laser diode array, and input beam 180 is thus a composite laser beam composed of the output from several laser diodes. The laser diode array can be operated to achieve a variety of intensity distributions 380, including a two-dimensional top-hat spatial intensity distribution. In another implementation, laser source 112 emits a single laser beam. In this implementation, laser source 112 may include a laser diode, a fiber laser, a fiber-coupled laser, or a combined output of several individual lasers. When laser source 112 emits only a single laser beam, this beam may be shaped to produce a desired intensity distribution 380. In one example, laser source 112 includes one or more lenses to perform such shaping. In another example, capable of producing a two-dimensional top-hat intensity distribution at output face 114, laser source 112 includes a light pipe, rectangular optical fiber, or a microlens array to shape input beam 180 at or before output face 114.

Certain potential applications of laser system 100 benefit from each line-beam segment 390 having a top-hat spatial intensity distributions, at least in the y-dimension. These applications include laser drying of extended surfaces such as laser drying of battery electrode coatings. Some of these applications, for example laser drying of battery-electrode coatings, may further benefit from the spatial intensity distribution of each line-beam segment being a top-hat also in the x-dimension. Laser system 100 is capable of meeting these needs.

In certain embodiments, prism array 120 samples only a portion of input beam 180. For example, prism array 120 may sample a central portion of input beam 180 having a more uniform intensity distribution than more peripheral portions of input beam 180. In such embodiments, each line-beam segment 390 generated by laser system 100 may have the same spatial intensity distribution as the sampled portion of input beam 180. Such partial sampling is less advantageous in terms of power efficiency but may be helpful for achieving a desired spatial intensity distribution for line-beam segments 390.

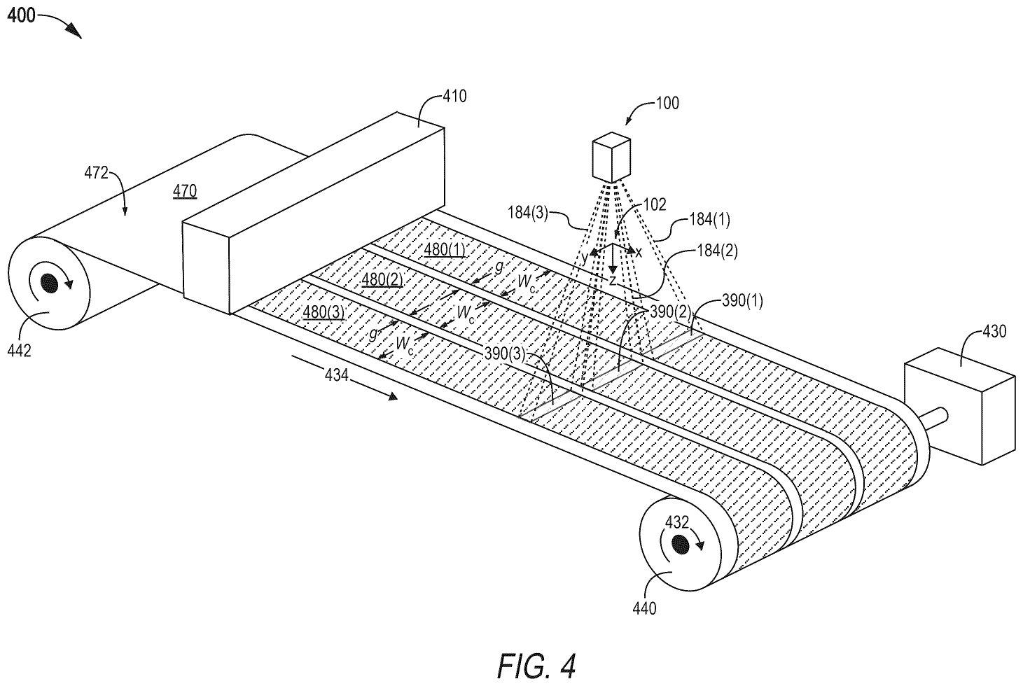

FIG. 4 illustrates one coating apparatus 400 that utilizes laser system 100 to simultaneously laser dry a plurality of parallel coating lanes 480 on a metal foil 470. Coating apparatus 400 may be used in the manufacture of battery electrodes, e.g., electrodes for lithium-ion or sodium-ion batteries. Once coated by coating apparatus 400, metal foil 470 may be cut to form a large number of coated battery electrodes. Coating apparatus 400 includes a coating applicator 410, laser system 100, and a transport system 430.

Transport system 430 drives metal foil 470 along a travel direction 434, allowing metal foil 470 to pass beneath coating applicator 410 and laser system 100. In the depicted implementation, transport system 430 pulls metal foil 470 from a feeding reel 442 to a receiving reel 440 by rotating receiving reel 440 as indicated by rotation direction 432. Alternatively, transport system 430 may utilize other techniques for transporting metal foil 470 beneath coating applicator 410 and laser system 100, such as rubberized wheels.

Herein, the terms “beneath” and “above” do not necessarily imply a particular positioning in relation to the direction of gravity. However, depending on the viscosity of the deposited coating material, it may be beneficial to keep the coated surface of metal foil 470 facing up, against the direction of gravity, to prevent the deposited coating material from running and/or detaching from metal foil 470 before the laser drying process is complete.

As metal foil 470 passes beneath coating applicator 410, coating applicator 410 deposits coating material on a surface 472 of metal foil 470 to form a plurality of parallel coating lanes 480 thereon. In the depicted embodiment, coating applicator 410 forms three coating lanes 480. More generally, coating applicator 410 forms two or more coating lanes 480. Each coating lane 480 has a width W_{c}, and coating lanes 480 are separated from each other by gaps g revealing the bare metal foil 470. In one example, width W_{c} is in the range between 1 and 100 centimeters (cm), and length L of line-beam segments 390 (see FIG. 3) substantially equals width W_{c}. Gaps g may be in the range between 0.5 and 15 cm, and the separation s between adjacent line-beam segments 390 may substantially match gap g.

Until dried, the material of coating lanes 480 may be in the form of a slurry. As deposited, the material of coating lanes 480 may include an active material, a binder, and a solvent. In one example, suitable for the manufacture of lithium-ion battery cathodes, metal foil 470 is an aluminum foil, and the material of each coating lane 480 includes a lithium oxide. For the manufacture of a lithium-ion battery anodes, metal foil 470 may be made of copper, a copper alloy, or nickel, and the material of each coating lane 480 may include graphite and/or silicon.

Laser system 100 is positioned downstream from coating applicator 410 and arranged such that metal foil 470 is situated in target plane 140 when passing beneath laser system 100. Each line-beam segment 390 (see FIG. 3) dries a corresponding coating lane 480 as it passes beneath laser system 100. The drying process performed by line-beam segments 390 may entail evaporating a solvent included in the deposited coating material. When implemented in coating apparatus 400, laser system 100 is configured to generate the same number of line-beam segments 390 as there are coating lanes 480 on metal foil 470. Additionally, line-beam segments 390 are (a) sized to match width W_{c} of coating lanes 480 and (b) separated from each other by distances that match gaps g. The separation between line-beam segments 390 at metal foil 470 prevents irradiation of the bare portions of metal foil 470 between coating lanes 480. If these bare metal foil portions were to be irradiated as intensely as coating lanes 480, the bare metal foil portions could heat up quickly and then cause over-drying and delamination of the adjacent edges of coating lanes 480.

The laser drying process performed by laser system 100 in coating apparatus 400 is best performed when each line-beam segment 390 is characterized by a top-hat spatial intensity distribution, at least in the widthwise dimension of coating lanes 480 (corresponding to the y-dimension in FIG. 3). The top-hat distribution provides the most even drying of the full width W_{c} of each coating lane 480. The laser drying process is typically most effective if each line-beam segment 390 is characterized by a top-hat spatial intensity distribution also in the lengthwise dimension of coating lanes 480 (corresponding to the x-dimension in FIG. 3).

Referring again to FIGS. 1A, 1B, and 3, when intensity distribution 380 at output face 114 of laser source 112 is a top-hat in both transverse dimensions, collimation lens 116 transforms this top-hat spatial intensity distribution to a uniform angular intensity distribution in both transverse dimensions. Input laser beam 180 is then incident on prism array 120 with a uniform two-dimensional angular intensity distribution. Each output beam 184 inherits this uniform angular intensity distribution, albeit shifted to different angular ranges for some or all of output beams 184 due to the deflection imposed by prism array 120. Field lens 130 transforms the two-dimensional uniform angular intensity distribution of each output beam 184 to a two-dimensional top-hat spatial intensity distribution at target plane 140.

When the objective is for each line-beam segment 390 to have a top-hat spatial intensity distribution at target plane 140, it suffices that input beam 180 is incident on prism array 120 with a uniform angular intensity distribution, regardless of how that uniform angular intensity distribution is achieved. In an associated modification of laser system 100, laser module 110 is replaced by a laser module that emits input beam 180 with a uniform angular intensity distribution. This laser module may or may not include collimation lens 116 and may or may not produce the uniform angular intensity distribution by transforming a top-hat spatial intensity distribution. For example, a uniform angular intensity distribution may instead be produced by a high-power diode laser with one or more microlens homogenizers (commonly referred to as fly's eye homogenizers). A single cylindrical-microlens array may produce homogenization in one axis only. Two crossed cylindrical-microlens arrays may two-dimensional homogenization. Two-dimensional homogenization may also be achieved by implementing custom shapes of the microlenses, e.g., rectangular. In another example, a uniform angular intensity distribution is achieved by including one or more waveguides in combination with a collimating lens or one or more diffractive elements.

In scenarios where a top-hat spatial intensity distribution of each output beam 184 at target plane 140 is required only for the y-dimension, laser module 110 (or another laser module in its place) may emit input beam 180 with a uniform angular intensity distribution in the y-dimension only. Alternatively, input beam 180 may have a uniform angular intensity distribution in both transverse dimensions, while field lens 130 is replaced by a cylindrical lens that acts only on the y-dimension of output beams 184.

Not all applications of laser system 100 require or benefit from a top-hat spatial intensity distribution for line-beam segments 390. Some applications may not even require that line-beam segments 390 are in-focus images of the output face of a laser source. Thus, in a generalization of laser system 100, (a) laser module 110 is replaced by a more general laser module that delivers input beam 180, collimated or not collimated, to prism array 120, and (b) field lens 130 projects output beams 184 onto target plane 140 where output beams 184 may or may not come to a focus. Still, generation of segmented line beam 188 in this generalization of laser system 100 relies on the deflection angle differences imposed by prism array 120 being greater than twice the divergence angle θ_{y} of input beam 180. Additionally, even when laser system 100 is not configured to form an in-focus image at target plane 140, it may be advantageous for input beam 180 to be incident on prism array 120 as a collimated beam.

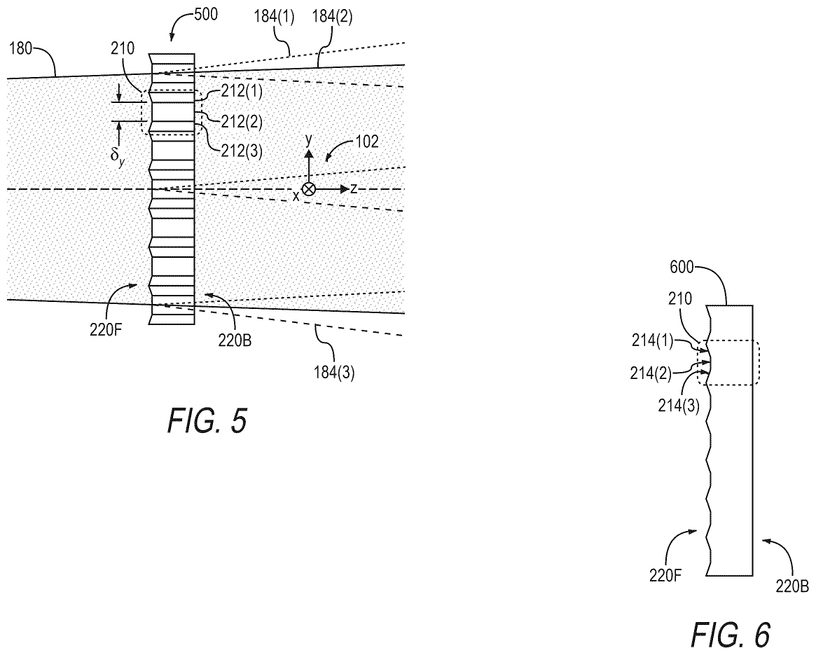

FIG. 5 is a cross sectional side-view of prism array 500 configured to split an input laser beam into a plurality of output beams 184 with uneven power sharing between output beams 184. Prism array 500 is an embodiment of prism array 200. Prism array 500 may be configured to generate three output beams 184, as depicted, or another number of output beams 184 greater than one. In the depicted embodiment of prism array 500, prism 212(2) of each prism block 210 has a greater width δ_{y} in the y-dimension than each of prisms 212(1) and 212(3). This results in a greater fraction of the power of input beam 180 being directed into output beam 184(2) than either one of output beams 184(1) and 184(3). In contrast, when each prism 212 has the same width in the y-dimension, the power of input beam 180 is shared evenly between output beams 184.

Prism 500 provides one example of how the y-dimension widths of individual prisms of prism array 200 can be sized to achieve a desired power sharing between output beams 184 in laser system 100. Another approach to achieving a desired power sharing between output beams 184 is to adjust the relative numbers of each type of prism 212. For example, instead of increasing the y-dimension width δ_{y} of prisms 212(2) of prism array 500, prism array 500 may include more prisms of the type of prism 212(2) than prisms of the type of either one of prisms 212(1) and 212(3). Such a configuration may be achieved by, e.g., inserting one or more additional prisms 212(2) into the embodiment depicted in FIG. 5.

Each of prism arrays 200 and 500 is configured as a series of identical prism blocks 210, whereby the different prism sets of the prism array are interleaved with each other. This may be optimal for achieving consistency in power and transverse intensity distribution between individual line-beam segments 390. However, prism array 120 does not need to be configured in this manner. The prism sets (e.g., the set of prisms 212(1), the set of prisms 212(2), and the set of prisms 212(3)) may be interleaved with each other in a less regular or even random fashion.

FIG. 6 illustrates one monolithic prism array 600. Prism array 600 is an embodiment of prism array 200, wherein surfaces 214 are portions of a continuous surface of a monolithic optical element. FIG. 6 illustrates, by example, that prism array 120, regardless of the exact configuration of individual prisms thereof, may be implemented as a monolithic optical element. Alternatively, prism array 120 may be an optical assembly including a series of individual prisms attached to each other or a series of prism blocks (e.g., prism blocks 210) attached to each other.

Referring again to FIGS. 1A and 1B, the position of target plane 140 along longitudinal axis 182 is substantially insensitive to the deflections imposed by prism array 120, at least as long as the deflection angles are relatively small (e.g., 20 degrees or less). As a result, it may be possible to switch between different embodiments of prism array 120 without having to redesign other aspect of laser system 100 and while keeping the same working distance between field lens 130 and target plane 140. This is advantageous from a use perspective since different applications may require, e.g., different numbers of line-beam segments, different separations between the line-beam segments, and/or different relative power sharing between the line-beam segments. In one scenario, laser system 100 first uses one embodiment of prism array 120 to laser dry battery-electrode coatings of one geometry, whereafter this embodiment of prism array 120 is replaced by another embodiment of prism array 120 to laser dry battery-electrode coatings of another geometry.

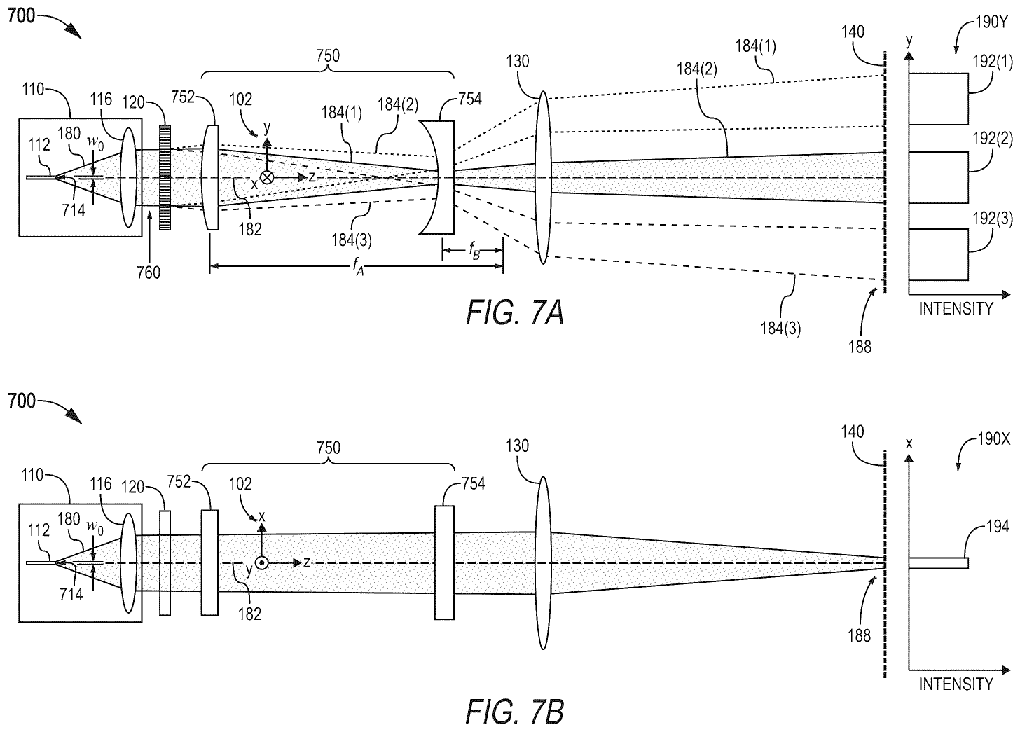

FIGS. 1A and 1B depicts an embodiment of laser system 100 wherein output face 114 of laser source 112 is elongated in the y-dimension as compared to the x-dimension. This results in each line-beam segment 390 (see FIG. 3) being elongated in the y-dimension as compared to the x-dimension. This depicted embodiment illustrates by example that a particular aspect ratio of each line-beam segment 390 can be achieved by implementing output face 114 with that same aspect ratio. Consider generalizations of laser system 100 wherein laser module 110 is replaced by a more general laser module that may or may not include laser source 112 and collimation lens 116 but rather emits input beam 180 with a certain angular intensity distribution. In these generalizations of laser system 100, the aspect ratio of this angular intensity distribution may be designed to achieve a particular aspect ratio of individual line-beam segments 390. Alternatively, or in combination therewith, cylindrical focusing elements may be implemented to manipulate the aspect ratio of line-beam segments 390. One such example is discussed below in reference to FIGS. 7A and 7B.

FIGS. 7A and 7B illustrate one laser system 700 that utilizes a prism array to generate a segmented line beam and utilizes a cylindrical telescope to manipulate the aspect ratio of individual line-beam segments. FIGS. 7A and 7B show orthogonal cross sections of laser system 100 taken in the yz- and xz-planes, respectively. Laser system 700 is similar to laser system 100 except for (a) laser source 112 having a square output face 714 emitting input beam 180 with the same initial width w₀ in the x- and y-dimensions and (b) further including a cylindrical telescope 750.

FIGS. 7A and 7B depict an example where width wo of input beam 180 at a square output face 714 (a) equals the x-dimension width wₓ of input beam 180 at rectangular output face 114 in laser system 100 (indicated in FIG. 1B) and (b) is significantly less than the y-dimension width w_{y} of input beam 180 at rectangular output face 114 in laser system 100 (indicated in FIG. 1A). Consider now the collimated section between laser module 110 and prism array 120, indicated by arrow 760 in FIG. 7A and arrow 160 in FIG. 1A. Since width w₀ in the depicted example of laser system 700 is less than the y-dimension width w_{y} in laser system 100, the y-dimension divergence of input beam 180 in collimated section 760 of laser system 700 is significantly less than the y-dimension divergence of input beam 180 in collimated section 160 of laser system 100. This lesser y-dimension divergence is inherited by each output beam 184 in laser system 700. Cylindrical telescope 750 serves to increase the y-dimension divergence of each output beam 184 in laser system 700.

Cylindrical telescope 750 is positioned between prism array 120 and field lens 130. Cylindrical telescope 750 changes the divergence of each output beam 184 in the y-dimension, thereby changing the length of each segment of segmented line beam 188 in the y-dimension. In the depicted embodiment, cylindrical telescope 750 includes a positive cylindrical lens 752 and a negative cylindrical lens 754. Cylindrical lenses 752 and 754 have respective focal lengths f_{A} and f_{B}, wherein f_{A}>f_{B}, and the distance between cylindrical lenses 752 and 754 is f_{A}−f_{B}. In this embodiment, cylindrical telescope 750 increases the divergence of each output beam 184 in the y-dimension, so as to increase the length of each segment of segmented line beam 188 in the y-dimension. As a result, each segment of segmented line beam 188 is elongated in the y-dimension as compared to the x-dimension.

Other configurations of cylindrical telescope 750 than the one depicted are possible. For example, cylindrical telescope 750 may be formed by two positive lenses, with the distance between the two positive lenses matching the sum of their respective focal lengths.

Cylindrical telescope 750 may also be positioned between laser module 110 and prism array 120 instead of between prism array 120 and field lens 130. When positioned between laser module 110 and prism array 120, cylindrical telescope 750 acts on input beam 180 instead of output beams 184. When cylindrical telescope 750 is positioned between prism array 120 and field lens 130, the entire spatial intensity distribution of segmented line beam 188 is stretched or compressed in the y-dimension. The ratio of segment length (e.g., length L in FIG. 3) to separation between adjacent segments (e.g., separation s in FIG. 3) remains the same. In contrast, when cylindrical telescope 750 is positioned between laser module 110 and prism array 120, the segment length is stretched or compressed, while the center-to-center distance between line-beam segments is unchanged. In this case, the separation between adjacent segments is compressed when the segment length is increased, and vice versa.

Advantageously, cylindrical telescope 750 does not affect the imaging system formed by collimation lens 116 and field lens 130. Therefore, one embodiment of cylindrical telescope 750 may be replaced by another embodiment of cylindrical telescope 750, or simply removed, without having to redesign other aspects of laser system 700. The position of target plane 140 remains the same. In this manner, and optionally in conjunction with selecting a different embodiment of prism array 120, laser system 700 can be reconfigured relatively easily to meet the requirements of different application scenarios.

In a modification of laser system 700, cylindrical telescope 750 is replaced by a cylindrical telescope that acts on the x-dimension instead of the y-dimension of output beams 184 (or input beam 180). For example, a cylindrical telescope may be used to decrease the divergence of output beams 184 (or input beam 180) in the x-dimension, so as to reduce the x-dimension width of segmented line beam 188. Laser system 700 may also include a combination of cylindrical telescopes that act on the x- and y-dimensions.

In either one of laser systems 100 and 700, and any one of the associated modifications and generalizations discussed above, field lens 130 may be replaced by field mirror, that is, a curved mirror that imparts the same optical power on output beams 184 as field lens 130. Such a field mirror will fold longitudinal axis 182. Similarly, although often not practical, collimation lens 116 (if included) may be replaced by a curved mirror with the same optical power as collimation lens 116. In addition, any one of the cylindrical telescopes discussed above may be implemented in the form of curved mirrors or a combination of a lens and a curved mirror. It is also possible to replace prism array 120 with a reflective element in the form of a mirror array, for example as discussed in the following.

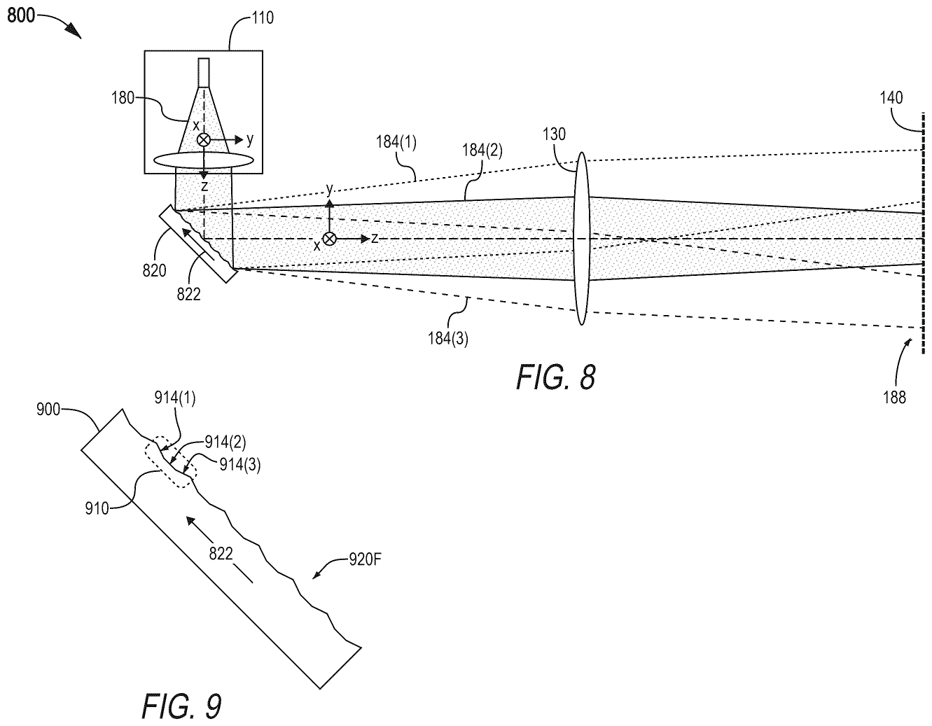

FIG. 8 illustrates one laser system 800 that utilizes a mirror array to generate a segmented line beam. Laser system 800 is similar to laser system 100 except that prism array 120 is replaced by a mirror array 820. Laser system 800 provides one example of how laser systems 100 and 700, and the associated modifications and generalizations discussed above, can be modified to utilize a mirror array instead of a prism array to split input beam 180. FIG. 8 shows a cross section of laser system 800 taken in the yz-plane.

FIG. 9 illustrates a mirror array 900 that may be implemented in laser system 800 as an embodiment of mirror array 820. FIG. 9 shows a cross section of mirror array 900 taken in the yz-plane. Mirror array 900 is a reflective analogue to prism array 200 (see FIG. 2).

Referring now to FIGS. 8 and 9 in combination, mirror array 900 is a one-dimensional array of mirrors distributed along a direction 822 that is (a) parallel to the yz-plane and (b) at oblique angles to both the y-axis and longitudinal axis 182 of input beam 180 as incident on mirror array 820. The mirrors of mirror array 900 are formed on a frontside 920F of mirror array 900 and are organized in a series of identical mirror blocks 910. Each mirror block 910 includes three planar mirror surfaces 914(1), 914(2), and 914(3). Each mirror surface 914 may include a reflective coating. Mirror surfaces 914(1), 914(2), and 914(3) are oriented at three different angles with respect to longitudinal axis 182 of the incident input beam 180. The collection of mirror surfaces 914 of mirror blocks 910 thereby form a multi-faceted reflective surface on frontside 920F.

The different orientation angles of mirror surfaces 914 lead to the production of output beams 184, similarly to the function of prism array 200 when implemented in laser system 100 except that mirror array 820 folds longitudinal axis 182. In the depicted embodiment, direction 822 is oriented at 45 degrees to longitudinal axis 182 of the incident input beam 180, and mirror array 820 therefore folds longitudinal axis 182 by ninety degrees. More generally, folding angles in the range between, but not including, 0 and 180 degrees are possible.

In one implementation, mirror array 900 is a substrate with a multi-faceted surface on frontside 920F. Each facet of this multi-faceted surface forms a respective one of mirror surfaces 914. Each facet may include a reflective coating.

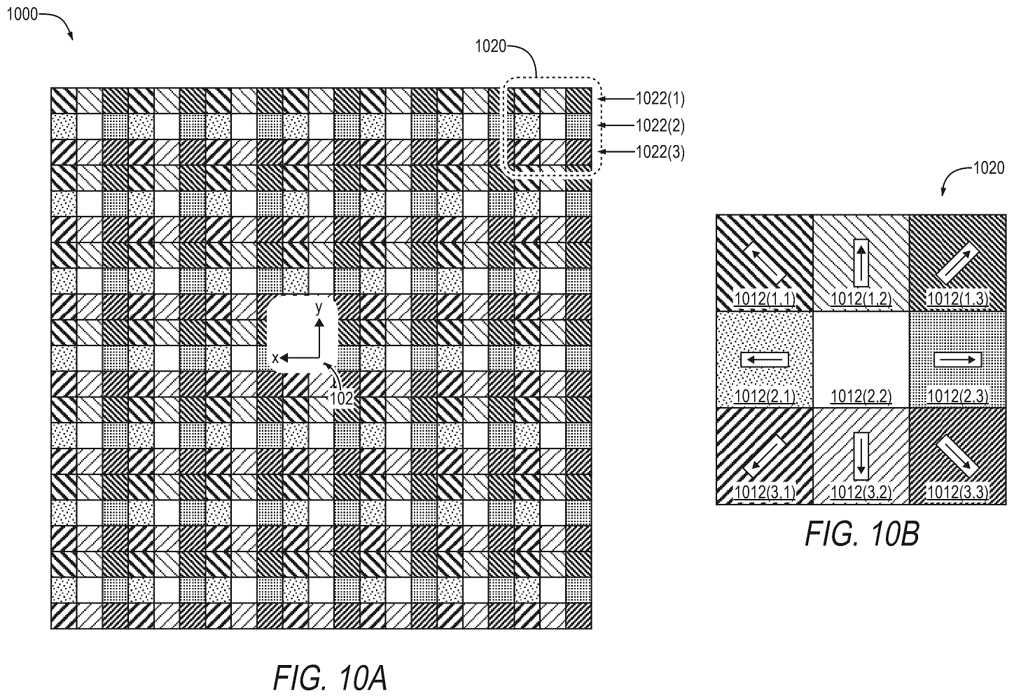

Laser systems 100, 700, and 800, as well as associated modifications and generalizations discussed above, may be extended to two-dimensional splitting of input beam 180 to form a plurality of segmented line beams situated side-by-side. Generally, this involves using a two-dimensional prism (or mirror) array. The two-dimensional prism (or mirror) array may be viewed as prism array 120 (or a corresponding mirror array) where each prism (or mirror) thereof has been segmented into an orthogonal one-dimensional array of prisms (or mirrors) imposing two or more different deflection angles in the xz-plane. One example is discussed below in reference to FIGS. 10A-12.

FIGS. 10A and 10B illustrate a two-dimensional prism array 1000 including a two-dimensional array of identical two-dimensional prism blocks 1020. FIG. 10A is a front view of prism array 1000. FIG. 10B shows an individual prism block 1020 in further detail. Each prism block 1020 includes a 3×3 array of prisms 1012, each imposing a different deflection angle on a laser beam incident thereon, as indicated by the boxed arrows in FIG. 10B. Considering first the horizontal rows of prism block 1020, prisms 1012(1,1), 1012(1,2) and 1012(1,3) impose deflection in the positive y-axis direction, prisms 1012(2,1), 1012(2,2) and 1012(2,3) impose no deflection in the yz-plane, and prisms 1012(3,1), 1012(3,2) and 1012(3,3) impose deflection in the negative y-axis direction. Considering then vertical columns of prism block 1020, prisms 1012(1,1), 1012(2,1) and 1012(3,1) impose deflection in the positive x-axis direction, prisms 1012(1,2), 1012(2,2) and 1012(3,2) impose no deflection in the xz-plane, and prisms 1012(1,3), 1012(2,3) and 1012(3,3) impose deflection in the negative x-axis direction.

Prism array 1000 may be viewed as an extension of prism array 200, wherein each prism 212(1) is segmented into a one-dimensional prism array 1022(1), each prism 212(2) is segmented into a one-dimensional prism array 1022(2), and each prism 212(3) is segmented into a one-dimensional prism array 1022(3). Each of prism arrays 1022 distributes its prisms 1012 along the x-axis.

The different types of prisms 1012 of prism array 1000 may be distributed such that each output beam produced by prism array 1000 samples essentially the same transverse area of the input beam.

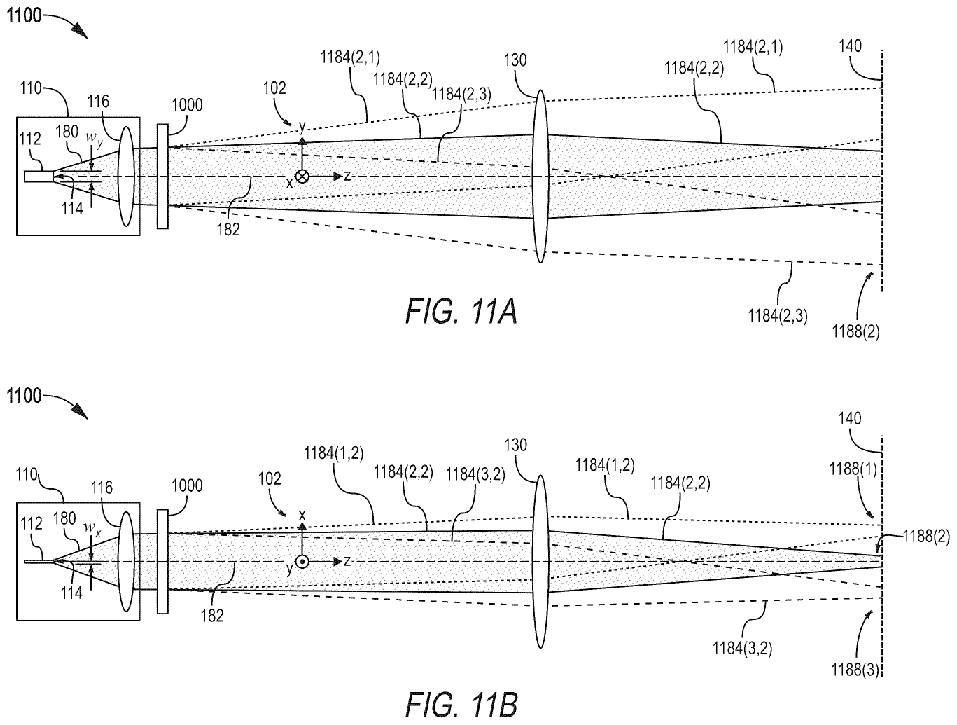

FIGS. 11A and 11B illustrate one laser system 1100 that utilizes prism array 1000 to generate a plurality of segmented line beams situated side-by-side. FIGS. 11A and 11B show orthogonal cross sections of laser system 1100 taken in the yz- and xz-planes, respectively. Laser system 1100 is similar to laser system 100 except for replacing prism array 120 with prism array 1000. Prism array 1000 splits input beam 180 into a 3×3 array of output beams 1184. Field lens 130 projects output beams 1184 onto target plane 140, where output beams 1184 form three segmented line beams 1188(1, 2, 3) offset from each other in the x-dimension.

FIG. 11A shows splitting and deflection by prism array 1000 in the yz-plane. FIG. 11B shows splitting and deflection by prism array 1000 in the xz-plane. Some of output beams 1184 leave the yz-plane and xz-plane and are therefore not indicated in FIGS. 11A and 11B. Each prism 1012(n,m) generates a corresponding output beam 1184(n,m), where n is 1, 2, or 3 and m is 1, 2, or 3.

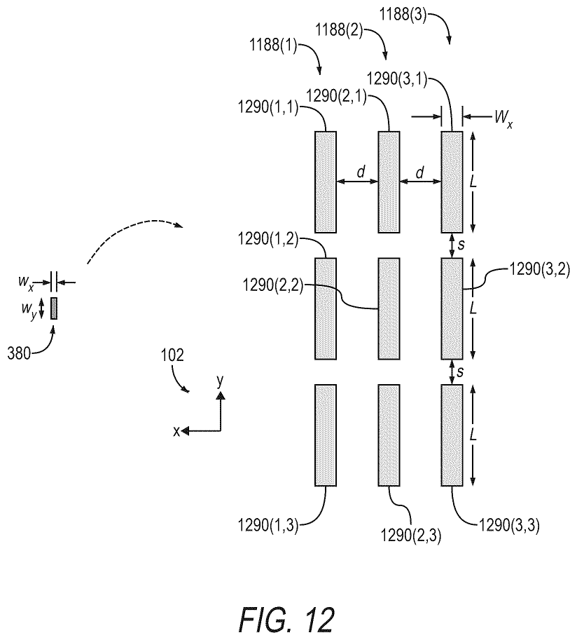

FIG. 12 is a diagram showing imaging in laser system 1100 of an exemplary initial spatial intensity distribution of input beam 180 at output face 114 to form the plurality of segmented line beams 1188 at target plane 140. The diagram of FIG. 12 is equivalent to the diagram of FIG. 3 but extended to the two-dimensional splitting and deflection imposed by prism array 1000. When focused by field lens 130, each output beam 1184(n,m) forms a corresponding line-beam segment 1290(n,m). Line-beam segments 1290(1,m) form a segmented line beam 1188(1), line-beam segments 1290(2,m) form a segmented line beam 1188(2), and line-beam segments 1290(3,m) form a segmented line beam 1188(3). Segmented line beams 1188 are offset from each other in the x-dimension. The separation distance d between adjacent segmented line beams 1188 is a function of the differences in deflection angles imposed by prism array 1000 in the xz-plane. Although not shown in FIG. 12, different pairs of adjacent segmented line beams 1188 may be separated by different distance d.

As already discussed for laser system 100, each of laser systems 700, 800, and 1100 may be generalized to not necessarily imaging a laser source onto a target plane. In such generalizations, (a) laser module 110 may be replaced by a more general laser module that delivers input beam 180, collimated or not collimated, to prism array 120, and (b) field lens 130 may project output beams 184 onto target plane 140 where output beams 184 may or may not come to a focus.

The present invention is described above in terms of a preferred embodiment and other embodiments. The invention is not limited, however, to the embodiments described and depicted herein. Rather, the invention is limited only by the claims appended hereto.

What is claimed is:

1. A laser system for generating a segmented line beam, comprising:
a laser module to emit an input laser beam;
a one-dimensional array of prisms arranged to receive the input laser beam, the array of prisms being distributed along a first transverse dimension of the input laser beam and organized in a plurality of prism sets interleaved with each other in the array, wherein each prism set of the plurality of prism sets is to impose on the input laser beam a different respective deflection angle in a propagation plane spanned by the first transverse dimension and a longitudinal axis of the input laser beam, whereby the plurality of prism sets splits the input laser beam into a respective plurality of output laser beams diverging from each other when propagating away from the array of prisms; and
a field lens or mirror arranged to project the output laser beams onto a target plane to form a segmented line beam at the target plane.

2. The laser system of claim 1, wherein a distance from the field lens or mirror to the target plane equals a focal length of the field lens or mirror.

3. The laser system of claim 1, wherein a smallest difference between any two of the deflection angles imposed by the array of prisms exceeds a full-angle of divergence of the input laser beam as incident on the array of prisms.

4. The laser system of claim 1, wherein one of the deflection angles is zero.

5. The laser system of claim 1, wherein the prisms are attached to each other in an optical assembly, or the array of prisms is a monolithic optical element.

6. The laser system of claim 1, wherein the prism array splits power of input laser beam evenly between the plurality of output laser beams.

7. The laser system of claim 1, wherein the input laser beam is incident on the array of prisms with a first width in the first transverse dimension, each prism set contains the same number of prisms within the first width, and each prism within the first width has the same size in the first transverse dimension.

8. The laser system of claim 1, wherein the prisms of the array are organized as a series of repeating contiguous blocks of prisms, each contiguous block containing one prism from each of the prism sets.

9. The laser system of claim 1, wherein the input laser beam is incident on the array of prisms as a collimated beam.

10. The laser system of claim 1, wherein:
the laser module includes (a) a laser source to generate the input laser beam, and (b) a collimation lens to collimate the input laser beam;
the array of prisms intercepts the input laser beam as collimated by the collimation lens; and
the collimation lens and the field lens or mirror together form an imaging system to image, onto the target plane, a spatial intensity distribution of the laser beam at an output face of the laser source.

11. The laser system of claim 10, wherein the output face is an end face of a rectangular optical fiber or light pipe.

12. The laser system of claim 1, wherein the laser source is a rectangular laser diode array.

13. The laser system of claim 1, further comprising a cylindrical telescope, disposed before the field lens or mirror, to change divergence of the input laser beam or each of the output laser beams in the first transverse dimension.

14. The laser system of claim 1, wherein:
the input laser beam is incident on the one-dimensional array of prisms with a uniform angular intensity distribution in the first transverse dimension, whereby each of the output laser beams inherits the uniform angular intensity distribution in the first transverse dimension; and
the field lens or mirror transforms the uniform angular intensity distribution in the first transverse dimension of each output laser beam to a top-hat spatial intensity distribution in the first transverse dimension at the target plane.

15. The laser system of claim 1, wherein:
the laser module includes (a) a laser source to generate the input laser beam such that the input laser beam, at an output of the laser source, has an initial top-hat spatial intensity distribution, and (b) a collimation lens to collimate the input laser beam and transform the initial top-hat spatial intensity distribution to a uniform angular intensity distribution;
the array of prisms intercepts the input laser beam as collimated by the collimation lens, whereby each of the output laser beams inherits the uniform angular intensity distribution; and
the field lens or mirror transforms the uniform angular intensity distribution of each output laser beam to a final top-hat spatial intensity distribution at the target plane.

16. The laser system of claim 1, wherein the input laser beam is incident on the one-dimensional array of prisms with a uniform angular intensity distribution, each of the output laser beams inherits the uniform angular intensity distributions, and the field lens or mirror transforms the uniform angular intensity distributions of each output laser beam to top-hat spatial intensity distributions at the target plane.

17. The laser system of claim 1, wherein each prism of the array comprises a one-dimensional array of sub-prisms distributed along a second transverse dimension of the laser beam orthogonal to the first transverse dimension, the array of sub-prisms being organized in a plurality of sub-prism sets interleaved with each other in the array of sub-prisms, each sub-prism set being configured to impose on the input laser beam a different respective deflection angle in an orthogonal plane spanned by the second transverse dimension and a longitudinal axis of the input laser beam, whereby the array of prisms, with the sub-prisms thereof, cooperates with the field lens or mirror to form a plurality of segmented line beams at the target plane, the segmented line beams being offset from each other in the second transverse dimension.

18. A battery-electrode coating apparatus, comprising:
a transport system to drive a metal foil along a lengthwise dimension thereof;
a coating applicator disposed above the metal foil to form a plurality of parallel coating lanes on the metal foil when the transport system drives the metal foil by the coating applicator; and
the laser system of claim 1 disposed after the coating applicator to dry each of the coating lanes with a respective one of the output laser beams as the transport system drives the metal foil through the segmented line beam at the target plane.

19. A laser system for generating a segmented line beam, comprising:
a laser module to emit an input laser beam;
a one-dimensional array of planar mirror surfaces arranged to receive the input laser beam, the array of mirror surfaces being distributed along a direction that is (a) parallel to a propagation plane spanned by a first transverse dimension and a longitudinal axis of the input laser beam and (b) at oblique angles to the first transverse dimension and the longitudinal axis, the array of mirror surfaces being organized in a plurality of mirror-surface sets interleaved with each other in the array, each mirror surface set of the plurality of mirror surface sets is to impose on the input laser beam a different respective deflection angle in the propagation plane, whereby the plurality of mirror surface sets splits the input laser beam into a respective plurality of output laser beams diverging from each other when propagating away from the array of mirrors; and
a field lens or mirror arranged to project the output laser beams onto a target plane to form a segmented line beam at the target plane.

20. The laser system of claim 19. including a substrate having a multifaceted surface, each facet of the multifaceted surface including a reflective coating to form a respective one of the mirror surface.
